(19) United States
(12) Patent Application Publication
(10) Pub. No.: US 2009/0140266 A1
(43) Pub. Date: Jun. 4, 2009

(54) PACKAGE INCLUDING ORIENTED DEVICES

(76) Inventors: Yong Liu, Scarborough, ME (US); Timwah Luk, Falmouth, ME (US); Zhongfa Yuan, Jiangsu (CN); Alister C. Young, Portland, ME (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/948,081

(22) Filed: Nov. 30, 2007

(51) Int. Cl. H01L 31/12; H01L 23/495; H01L 21/60; H01L 33/00

(52) U.S. Cl. 257/82; 257/676; 438/123; 438/27; 257/E31.095; 257/E33.077; 257/E23.031; 257/E21.506

(57) ABSTRACT

An package such as an optocoupler package is disclosed. The optocoupler package includes a leadframe structure comprising a first die attach pad comprising a first die attach pad surface and a second die attach pad with a second die attach pad surface. The optocoupler package further has an optical emitter device on the first die attach pad, and an optical receiver device on second die attach pad. The optical receiver device is oriented at an angle with respect to the optical emitter device, and an optically transmissive medium is disposed between the optical emitter device and the optical receiver device.

### CROSS-REFERENCE TO RELATED APPLICATIONS

This application is related to U.S. patent application Ser. No. ______ entitled “Package Including Clip Attach Structure” (Attorney Docket No. 018865-026600US), which is being filed on the same day as the present application, and is herein incorporated by reference in its entirety for all purposes.

### BACKGROUND OF THE INVENTION

Optocouplers contain at least one optical emitter device which is optically coupled to an optical receiver device through an optically transmissive medium. This arrangement permits the passage of information from one electrical circuit that contains the optical emitter device to another electrical circuit that contains the optical receiver device. A high degree of electrical isolation is maintained between the two circuits. Because information is passed optically across an insulating gap, the transfer is one way. For example, the optical receiver device cannot modify the operation of a circuit containing the optical emitter device. This feature is important because, for example, the emitter may be driven by a low voltage circuit using a microprocessor or logic gates, while the output optical receiver device may be part of a high voltage DC or AC load circuit. The optical isolation also prevents damage to the input circuit caused by the relatively hostile output circuit.

FIG. 1 shows a side view of a conventional optocoupler package 10. The illustrated optocoupler 10 includes a substrate 24, and solder balls 18 on the substrate 24. An LED (light emitting diode) device 16 including an optical emitter surface 16(a) and a phototransistor device 12 (including an optical receiver surface 12(a)) are on the substrate 24 and are covered by an optically transmissive medium 22.

The output current generated by the phototransistor (diode) device 12 is low (e.g., about several nA to tens of μA, and can be the same level as noise) due to the low efficiency of the phototransistor 12 device to receive very limited light emitted by the LED device 16. This is because the optical receiver surface 12(a) of phototransistor device 12 does not face the optical emitting surface 16(a) of LED device 16. Consequently, light rays 20 from the LED device 16 hit the optical receiver device 12 and the optical receiver surface 12(a) of photo transistor (or diode) less than 10% of the time.

Embodiments of the invention address this problem and other problems, individually and collectively.

### SUMMARY OF THE INVENTION

Embodiments of the invention are directed to optocoupler packages, optocoupler assemblies, and methods for making the same.

One embodiment of the invention is directed to a package comprising a leadframe structure comprising a first die attach pad comprising a first die attach pad surface and a second die attach pad comprising a second die attach pad surface, a first device on the first die attach pad, and a second device on second die attach pad, wherein the second device is oriented at an angle with respect to the first device.

Another embodiment of the invention is directed to an optocoupler package. The optocoupler package comprises a leadframe structure comprising a first die attach pad comprising a first die attach pad surface and a second die attach pad comprising a second die attach pad surface. The optocoupler package further comprises an optical emitter device on the first die attach pad, and an optical receiver device on second die attach pad. The optical receiver device is oriented at an angle with respect to the optical emitter device, and an optically transmissive medium is disposed between the optical emitter device and the optical receiver device.

Another embodiment of the invention is directed to an assembly including the optocoupler package.

Another embodiment of the invention is directed to a method comprising obtaining a leadframe structure comprising a first die attach pad comprising a first die attach pad surface and a second die attach pad comprising a second die attach pad surface, attaching a first device to the first die attach pad, and attaching a second device to the second die attach pad, wherein the second device is oriented at an angle with respect to the first device.

Another embodiment of the invention is directed to a method comprising: obtaining a leadframe structure comprising a first die attach pad comprising a first die attach pad surface and a second die attach pad comprising a second die attach pad surface, and then attaching an optical emitter device to the first die attach pad, and attaching an optical receiver device to the second die attach pad, wherein the optical receiver device is oriented at an angle with respect to the optical emitter device. After the optical emitter device and the optical receiver device are attached to the first and second die attach pads, respectively, an optically transmissive medium is deposited between the optical emitter device and the optical receiver device.

These and other embodiments of the invention are described in further detail below with reference to the Drawings.

### BRIEF DESCRIPTION OF THE DRAWINGS

FIG. 1 shows a diagram of a conventional optocoupler package.

FIG. 2 shows a perspective view of an optocoupler package according to an embodiment of the invention, where the components inside of the optocoupler package can be seen.

FIGS. 3(a), 3(b), and 3(c) respectively show top, and side views of the optocoupler package embodiment shown in FIG. 2, where components inside of the optocoupler package can be seen.

FIG. 4 shows a perspective view of an optocoupler package according to an embodiment of the invention, where the components inside of the optocoupler package can be seen.

FIGS. 5(a), 5(b), and 5(c) respectively show top, and side views of the optocoupler package embodiment shown in FIG. 4, where components inside of the optocoupler package can be seen.

FIG. 6(a) shows a side view of a leadframe structure that can be used in the optocoupler package embodiment shown in FIG. 1.

FIGS. 6(b) and 6(c) respectively show perspective and side views of a leadframe structure that can be used in the optocoupler package embodiment shown in FIG. 4.

FIGS. 7(a) and 7(b) show perspective views of components in an optocoupler package as it is being formed.

FIGS. 8(a)-8(i) shows various close-up perspective views of portions of components in an optocoupler package as it is being formed.

FIGS. 9(a)-9(e) show various close-up perspective views of portions of components in an optocoupler package as it is being formed.

In the Figures, like numerals designate like elements.

### DETAILED DESCRIPTION

One embodiment of the invention is directed to a package comprising a leadframe structure comprising a first die attach pad comprising a first die attach pad surface and a second die attach pad comprising a second die attach pad surface, a first device on the first die attach pad, and a second device on second die attach pad, wherein the second device is oriented at an angle with respect to the first device.

In preferred embodiments of the invention, the first device is an optical emitter device such as an LED and the second device is an optical receiver device. However, in other embodiments, the first and/or the second device could be purely electrical devices such as MOSFETs, control ICs, etc.

Embodiments of the invention have a number of unique features. For example, embodiments of the invention provide for vertical alignment of an optical receiver device such as a phototransistor and an optical emitter device such as an LED in an optocoupler package. The optical receiver surface of the phototransistor (or diode) partially or completely faces the optical emitter surface of the LED.

Embodiments of the invention are also directed to a method for forming a leadframe structure with vertically oriented die attach pads. The vertically oriented die attach pads provide a vertical platform for mounting a phototransistor (or diode) device and for an associated bond wire connection.

In some embodiments, the optocoupler package also includes a leadframe structure having a die attach pad that has a downset portion. This can be used to adjust the position of transistor (or diode) and can be used to centrally align the LED and the transistor. This results in an optimized photo-electrical conversion ratio.

In some embodiments of the invention, the methods may include attaching optical emitter and optical receiver devices onto die attach pads of a leadframe structure. The orientation of the leadframe structure may be changed during the manufacturing process to allow for die mounting. Other methods include methods for forming a gel dome and a molding material in the optocoupler package.

Embodiments of the invention solve a number of problems. For example, embodiments of the invention improve the photoelectrical conversion ratio between an optical emitter device such as an LED die and an optical receiver device such as a photo-transistor (or diode) die, by directly facing the optical emitting surface of the optical emitter device to the optical receiver surface of optical receiver device. In some embodiments, this causes the light from the optical emitter device to hit the optical receiver surface of the optical receiver device more than 80% of the time.

Embodiments of the invention provide a solution for any packages that may need to align vertical devices. Also, in some embodiments of the invention, the optocoupler may have a standard BGA type of foot print or may have a standard surface mount type like an LGA foot print (without solder balls).

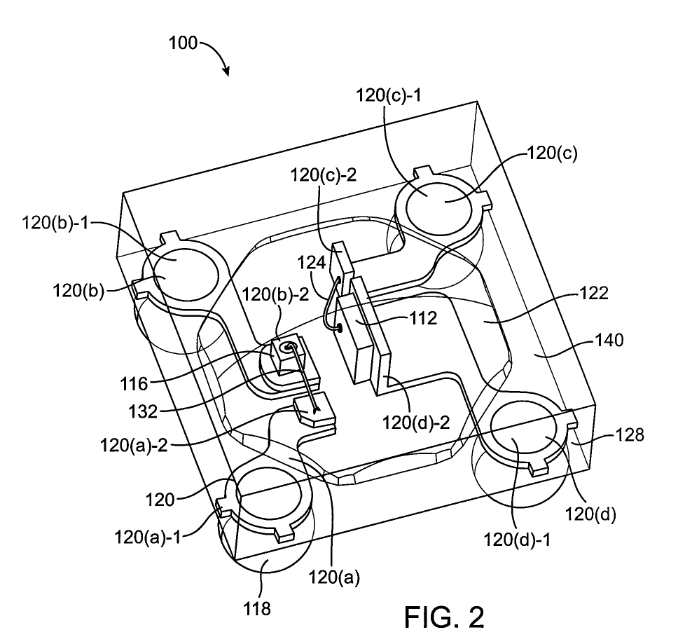

FIG. 2 shows an optocoupler package 100 according to an embodiment of the invention. Optocoupler packages according to embodiments of the invention can include at least one optoelectronic device. Any suitable optoelectronic device can be used in embodiments of the invention. For example, the optocoupler package 100 may comprise an optical emitter device 116, which may be fabricated from silicon, gallium arsenide, or any other solid-state material(s) and can emit radiation (e.g., infrared, visible) that can be detected by an optical receiver device 112. An example of an optical emitter device is an LED (light emitting diode) device. Examples optical receiver devices include phototransistors and photodetector diodes. The optical receiver device 112 may also be formed from a semiconductor material such as silicon (but not limited to silicon). Although the package 100 shown in FIG. 2 has one optical emitter device and one optical receiver device, it is understood that the packages according to embodiments of the invention may have more than one optical emitter device and/or more than one optical receiver device. Embodiments of the invention may also have devices which perform only electrical functions (e.g., MOSFETs).

In this example, the optocoupler package 100 comprises a leadframe structure 120 having first, second, third, and fourth leadframe structure portions 120(a), 120(b), 120(c), 120(d). The first, second, third and fourth leadframe structure portions 120(a), 120(b), 120(c), 120(d) are physically separate structures in FIG. 2. The leadframe structure 120, and any portions thereof, may be formed by any suitable process including etching, stamping, etc.

The second and fourth leadframe structure portions 120(b), 120(d) include connection pads 120(b)-1, 120(d)-1, and corresponding die attach pads 120(b)-2, 120(d)-2. Each connection pad 120(b)-1, 120(d)-1 and corresponding die attach pad 120(b)-2, 120(d)-2 can be joined together by an integral intermediate portion. As shown in FIG. 2, the die attach pads 120(b)-2, 120(d)-2 can be defined by a partial etching process, and they may be characterized as “partially etched” pads (e.g., half-etched pads). Etching processes are well known to those of ordinary skill in the art.

The first and third leadframe structure portions 120(a), 120(c) comprise connection pads 120(a)-1, 120(c)-2 and bonding pads 120(a)-2, 120(c)-2, connected by integral intermediate portions. As shown in FIG. 2, the bonding pads 120(a)-2, 120(c)-2 can be defined by a partial etching process, and they may be characterized as “partially etched” pads (e.g., half-etched pads).

An optical emitter device 116 is attached to the die attach pad 120(b)-2 using a conductive adhesive such as solder (not shown). A wirebond 132 is formed between the optical emitter device 116 and the bonding pad 120(a)-2. The wirebond 132 may comprise a metal wire such as a wire comprising gold, copper, aluminum, or any suitable alloy thereof.

An optical receiver device 112 is also attached to the die attach pad 120(d)-2 using a conductive adhesive such as solder. A wirebond 124 is formed between the optical receiver device 112 and the bonding pad 120(c)-2. The wirebond 124 may comprise a metal wire such as a wire comprising gold, copper, aluminum, or any suitable alloy thereof.

An optically transmissive material 122 covers the die attach pads 120(b)-2, 120(d)-2, as well as the bonding pads 120(a)-2, 120(c)-2. It also covers the optical emitter device 116 and the optical receiver device 112. The optically transmissive material 122 is in turn covered with an opaque molding material 140 (e.g., an epoxy molding material). A reflective coating (not shown) such as a silver paint or the like may be coated over the light transmissive material 122 to keep light within the optically transmissive material 122.

The optically transmissive material 122 may comprise an optical grade, silicone die coat material (e.g., a “glob top” type encapsulant). In some embodiments, the area over which the optically transmissive medium 122 is spread can have a size on the order of millimeters (e.g., less than about 1.6×1.6 mm²).

The bonding pad 120(c)-2 and the die attach pad 120(d)-2, and the surfaces thereof, are oriented substantially perpendicular to the die attach pad 120(b)-2 and bonding pad 120(a)-2. Consequently, the orientation of the optical emitter device 116, which is mounted on the die attach pad 120(b)-2, has its light emitting surface oriented substantially perpendicular to the orientation of the optical receiver device 112. This allows the emitter surface of the optical emitter device 116 to provide light substantially directly to the receiver surface of the optical receiver device 112. Although the light emitting surface of the optical emitter device 116 and the optical receiver device 112 are oriented at an approximately 90 degree angle in this embodiment, they may be oriented at any suitable angle in other embodiments of the invention. For example, they could be oriented at an angle of about 45 or even about 135 degrees with respect to each other in other embodiments of the invention.

Solder balls 118 are attached to the underside of each of the connection pads 120(a)-1, 120(a)-2, 120(a)-3, 120(a)-4, so that the package 100 is a BGA (ball grid array) type package. Exemplary solder balls can have a radius on the order of about 1 mm (e.g., 0.75 mm) or less. The solder balls 118 may act as input/output terminals for the optical emitter device 116 and the optical receiver device 112. While many of the specific embodiments discussed with reference to the figures use solder balls, it is understood that the solder balls could be replaced by other suitable conductive structures including conductive columns (e.g., electroplated columns such as electroplated copper columns).

As shown, the optical receiver device 112 and the optical emitter device 116 are on one side of the leadframe structure 120, and a plurality of solder balls 118 (or other conductive structures) is disposed at a second side of the leadframe structure 120 where the first side of the leadframe structure 120 is opposite to the second side of the leadframe structure 120.

While such packages may have any suitable dimensions, exemplary dimensions may be about 3.5 mm by 3.5 mm, with a thickness of about 1.8 mm including solder balls if they are BGA type packages, or about 1.1 mm if the packages do not have solder balls and are LGA type packages.

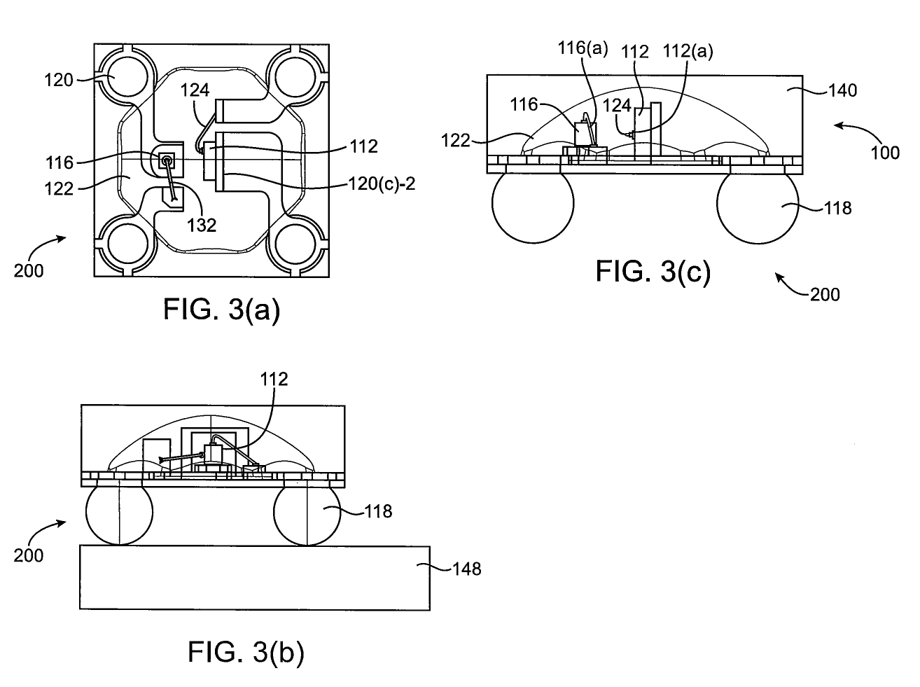

FIGS. 3(a), 3(b), and 3(c) show top, and two different side views of the package shown in FIG. 2.

As shown in FIG. 3(b), the previously described optocoupler package 100 can be mounted on a circuit substrate 148 such as a circuit board or the like. For simplicity of illustration, the various layers, pads, etc. of the circuit substrate 148 are not shown in FIG. 3(b).

As shown in FIG. 3(c), the emitter surface 116(a) of the emitter device 116 faces the receiver surface 112(a) of the optical receiver device 112. As such, light emitted from emitter surface 116(a) is efficiently transmitted to the receiver surface 112(a) of the optical receiver device 112. As shown, the emitter surface 116(a) can be substantially parallel to the receiver surface 112(a).

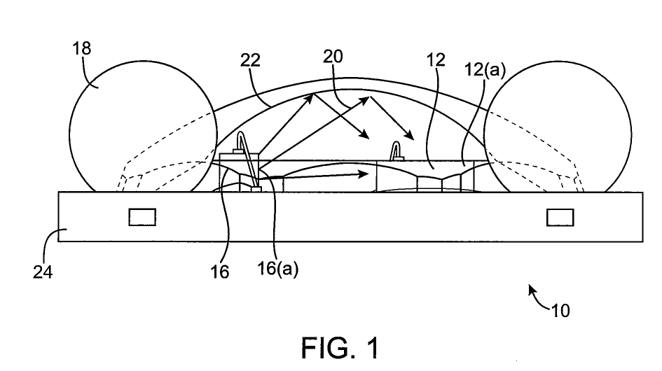

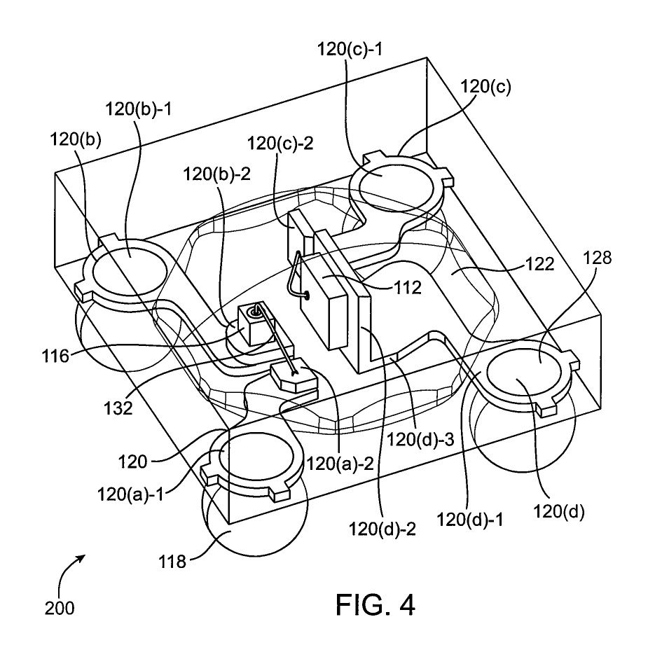

FIG. 4 shows another optocoupler package 200 according to another embodiment of the invention. The optocoupler package 200 has many of the same features as the optocoupler package shown in FIG. 1, except that a downset portion 120(d)-3 is present between the die attach pad 120(d)-2 for the optical receiver device 112 and the connection pad 120(d)-1 in the fourth leadframe structure portion 120(d).

The downset portion 120(d)-3 can be formed in any suitable manner. For example, a leadframe structure without a downset portion can be first formed, and then the leadframe structure can be bent or otherwise shaped to form the downset portion 120(d)-3.

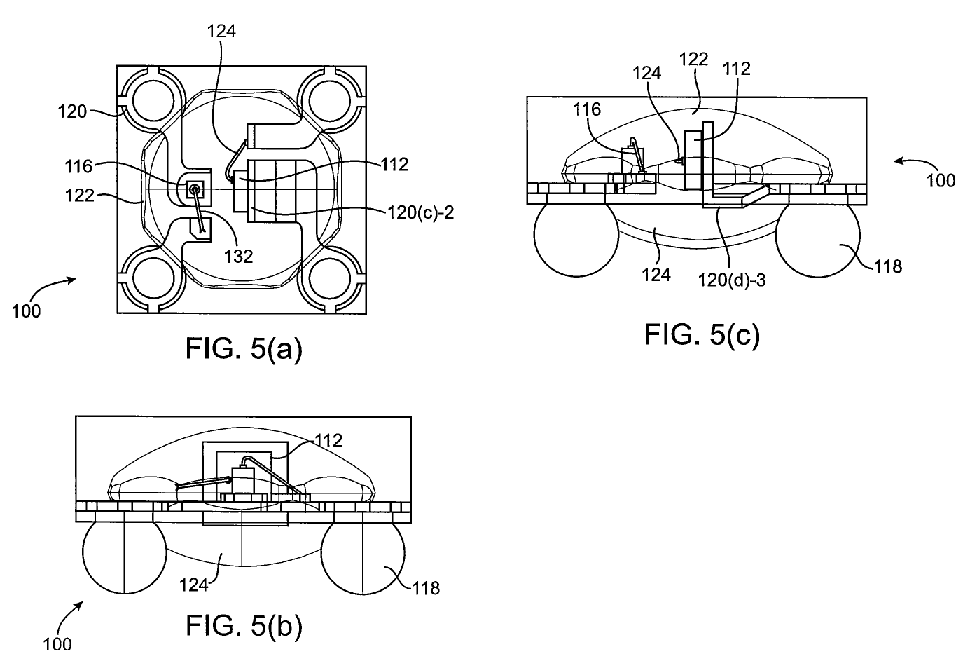

FIGS. 5(a), 5(b), and 5(c) show top, and two different side views of the package shown in FIG. 4. Compared to the optocoupler package 100 shown in FIG. 2, the optocoupler package 200 shown in FIGS. 5(b) and 5(c) additionally comprises an additional coating material 124 (e.g., a gel coating material) on the bottom of the leadframe structure 120. The coating material 124 may cover at least some of the bottom surfaces of the downset portion 120(d)-3 so that it is protected from the environment. The coating material 124 may be formed between the solder balls 118.

The downset portion 120(d)-3 provides a number of advantages. As shown in FIGS. 5(b) and 5(c), the downset portion 120(d)-3 lowers the die attach pad 120(c)-3, which in turn vertically aligns the optical receiver device 112 and the optical emitter device 116. As there is a more direct path between the optical receiver device 112 and the optical emitter device 116, the transmission of light from the optical emitter device 116 to the optical receiver device 112 is more efficient.

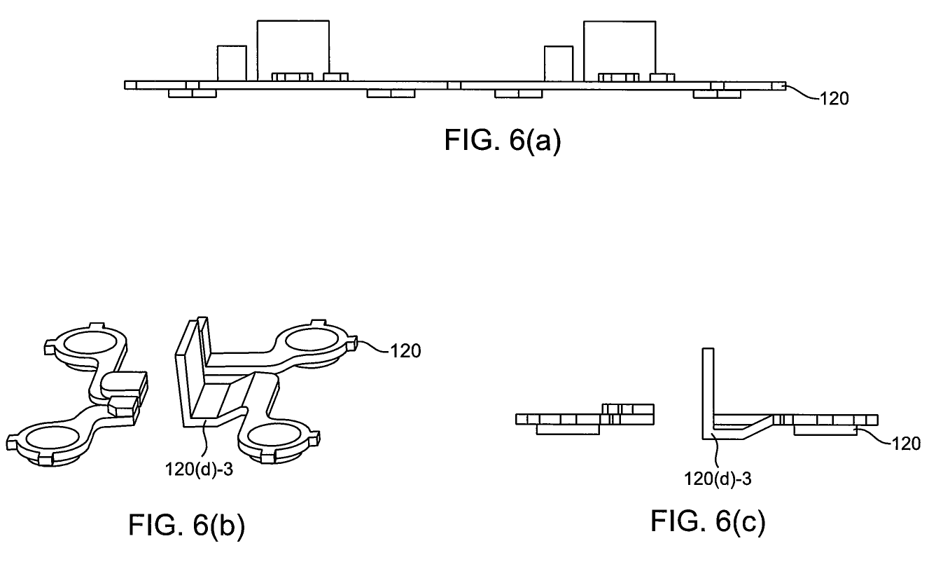

FIG. 6(a) shows a leadframe structure 120 without a downset portion. The leadframe structure 120 can be used in an optocoupler package 100 of the type shown in FIG. 2. FIGS. 6(b) and 6(c) respectively show perspective and side views of a leadframe structure 120 with a downset portion 120(d)-3. The leadframe structure 120 shown in FIGS. 6(b) and 6(c) can be used in the optocoupler package 200 shown in FIG. 4.

Various methods for making optocoupler packages can be now be described. One embodiment of the invention is directed to a method comprising obtaining a leadframe structure comprising a first die attach pad comprising a first die attach pad surface and a second die attach pad comprising a second die attach pad surface, attaching an optical emitter device to the first die attach pad, attaching an optical receiver device to the second die attach pad, wherein the optical receiver device is oriented at an angle with respect to the optical emitter device, and depositing a medium between the optical emitter device and the optical receiver device.

This medium serves two purposes: First, the material is a good photo-transmissive dielectric material. Second, when properly chosen, this dielectric material's high relative static permittivity can help sustain a much higher potential difference with a smaller gap between the two circuits described previously. Furthermore, if the isolation requirement is less than 10 Mega Volts/cm, the gap between the two circuits is not limited by the final package size, and the optical conversion efficiency is sufficiently high in this embodiment of the invention. It is possible to eliminate this dielectric medium entirely to further reduce cost in some embodiments.

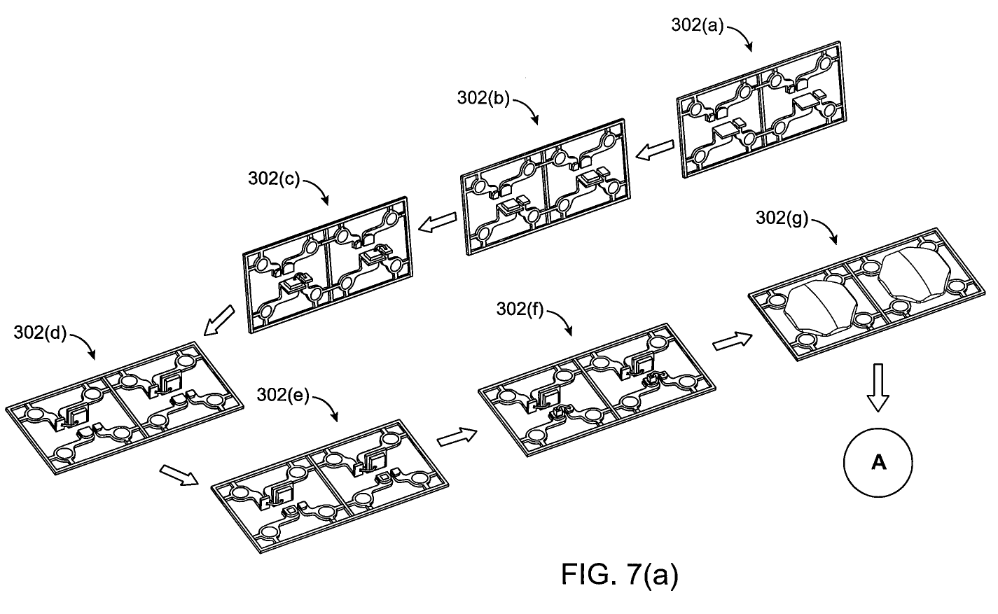

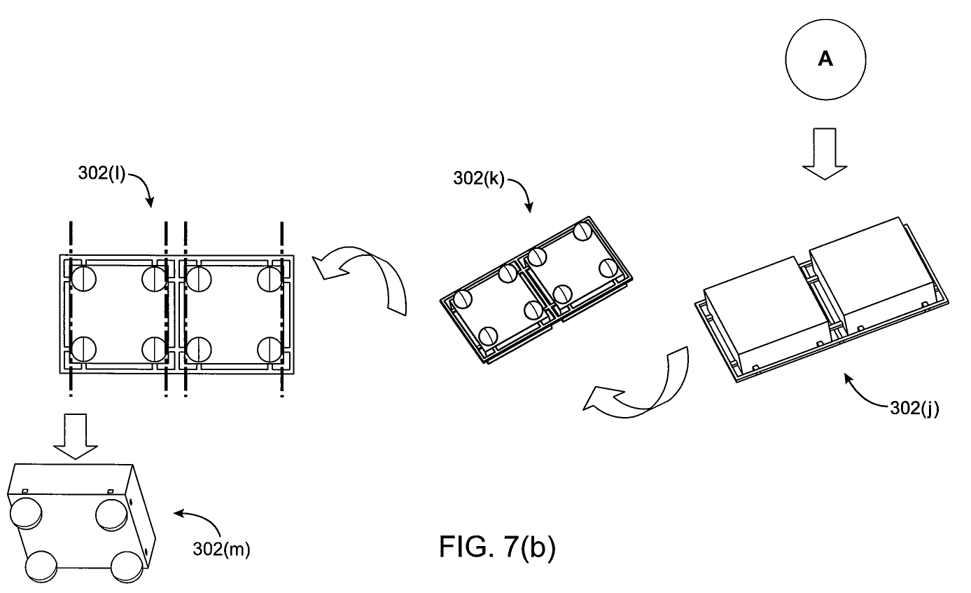

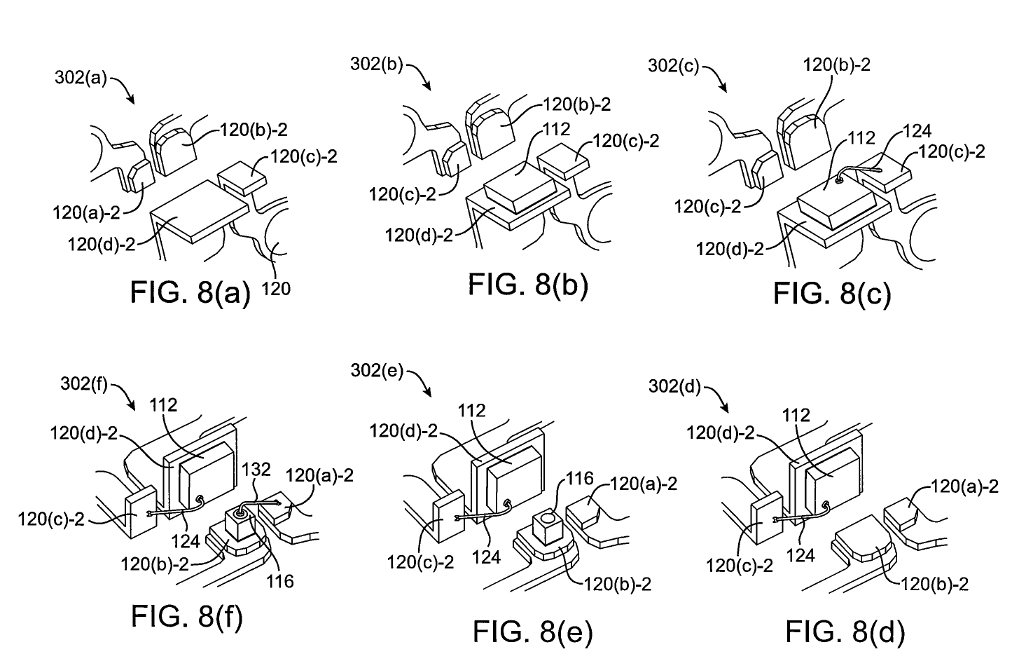

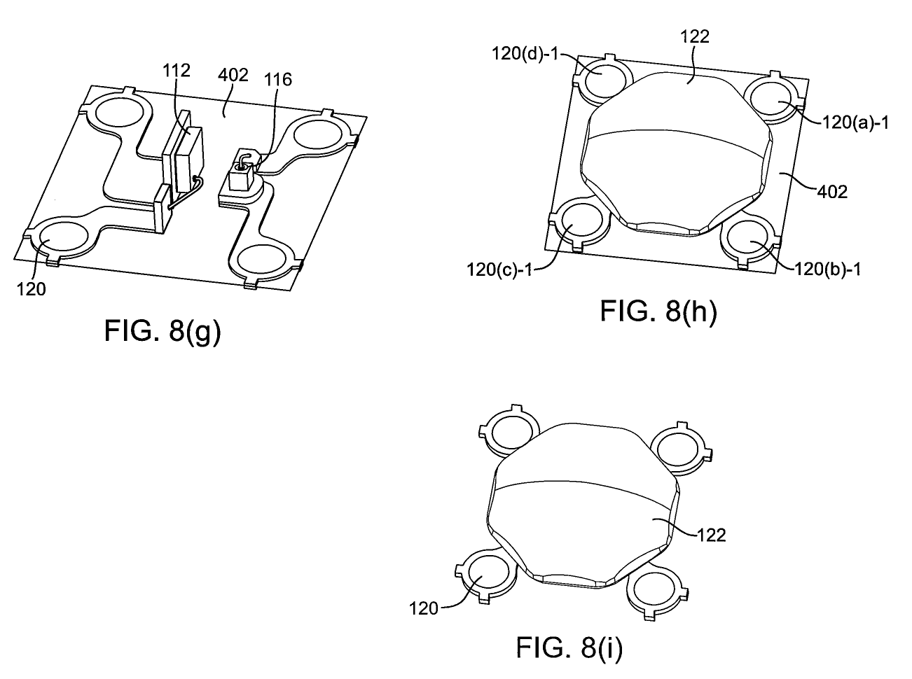

FIGS. 7(a) and 7(b) show process flows for forming optocoupler packages according to embodiments of the invention. The process flows in FIGS. 7(a)-7(b) can also be described with reference to FIGS. 8(a)-8(i). The descriptions of specific components like those described above are herein incorporated by reference, and need not be repeated. For example, the specific descriptions of solder balls above may apply to the descriptions of solder balls below.

Also, although the process flows described below are described in particular orders, it is understood that embodiments of the invention are not limited to the specific order of steps shown. For example, in the specific process flows described below, an optical receiver device is mounted on its corresponding die attach pad of the leadframe structure before an optical emitter device is mounted to its corresponding die attach pad. It is understood that embodiments of the invention may include methods whereby an optical emitter device is mounted on its corresponding die attach pad of the leadframe structure before an optical receiver device is mounted to its corresponding die attach pad.

As shown in FIG. 7(a), an array of leadframe structures is first obtained (step 302(a)). The leadframe structures may be similar to the leadframe structure 120 shown in FIG. 2. The leadframe structures may be formed by etching, stamping, etc. FIG. 8(a) shows a close up view of the die attach pads 120(b)-2, 120(d)-2 and bonding pads 120(a)-2, 120(c)-2 in a single leadframe structure 120.

Referring to FIG. 7(a), after the leadframe structures are formed or otherwise obtained, optical receiver devices may be mounted on corresponding die attach pads (step 302(b)). FIG. 8(b) shows an optical receiver device 112 mounted on a corresponding die attach pad 120(d)-2. The optical receiver devices may be mounted using any suitable process and using any suitable adhesive material. The adhesive material may be present on the die attach pad 120(d)-2 and/or the bottom of the optical receiver device 112 prior to mounting the optical receiver device 112 to the die attach pad 120(d)-2. Suitable materials for mounting the optical receiver devices may include solder, conductive epoxies, etc.

Referring to FIG. 7(a), after the optical receiver devices are mounted to the die attach pads in the leadframe structures, the optical receiver devices may be wirebonded to corresponding bonding pads (step 302(c)). As shown in FIG. 8(c), a wirebond 124 may be formed between the optical receiver device 112 and a corresponding bond pad 120(c)-2. Wirebonding processes are known to those of ordinary skill in the art. Alternatively, instead of a wirebond, another conductive connector structure such as a conductive clip could be used.

Referring again to FIG. 7(a), after the wirebonding process, the array of leadframe structures is turned (step 302(d)). FIG. 8(d) also shows the turning of a single leadframe structure. Before turning, the die attach pad 120(d)-2 and the bonding pad 120(c)-2 were oriented substantially horizontally so that the optical receiver device 112 could be easily attached to the die attach pad 120(d)-2 and to make the wirebonding process easier. After turning, the die attach pad 120(d)-2 and the bonding pad 120(c)-2 are oriented substantially vertically, and the die attach pad 120(b)-2 and the bonding pad 120(a)-2 are oriented substantially horizontally so that the mounting of the optical emitter device 116 and the wirebonding process associated with the optical emitter device 116 is easier. In this example, the leadframe structure 120 is rotated about 180 degrees in a horizontal plane, and is then rotated 90 degrees upward in the vertical direction to arrive at the position shown in step 302(d). The magnitude of turning and/or the orientation of turning the leadframe structure 120 can be different in other embodiments of the invention.

Referring to FIG. 7(a), after turning, the optical emitter devices are mounted to corresponding die attach pads in the leadframe structures (step 302(e)). The same or different die attach process can be used as was used to attach the optical receiver devices to the die attach pads. FIG. 8(e) shows an optical emitter device 116 attached to a corresponding die attach pad 120(b)-2.

Referring to FIG. 7(a), after the optical emitter devices are mounted to the corresponding die attach pads, wirebonds are formed between the optical emitter devices and corresponding bonding pads (step 302(f)). FIG. 8(f) shows an optical emitter device 132 bonded to a die attach pad, and a wirebond 132 attached to the optical emitter device 132 and a corresponding bond pad 120(a)-2.

Referring again to FIG. 7(a), after the wirebonding process is performed, a light transmissive material can be deposited on the optical emitter devices and optical receiver devices, as well as the wirebonds (step 302(g)). As shown in FIG. 8(g), a temporary substrate 402 such as paper may be placed under a leadframe structure 120. Then, as shown in FIG. 8(h), the light transmissive material 122 is deposited over the optical emitter device 116 and the optical receiver device 112, and on portions of the leadframe structure 120 and the temporary substrate 402. As shown in FIG. 8(h), the pads 120(a)-1, 120(a)-2, 120(a)-3, and 120(a)-4 are not covered by the light transmissive material 122 and the light transmissive material is present within the borders of the temporary substrate 402. After the light transmissive material 122 is deposited and cured, the temporary substrate 402 can be removed.

Referring now to FIG. 7(b), a molding process can take place by molding a molding material over the previously deposited light transmissive material (step 302(j)). Suitable molding processes are known to those of ordinary skill in the art.

After molding, solder balls are attached to the previously described bonding pads (step 302(k)). The array of optocoupler packages are then flipped over (step 302(l)) and the optocoupler packages are then separated from each other (step 302(m)). A saw or the like can be used to separate the optocoupler packages from each other, but cutting the tie bars that previously joined the optocoupler packages together.

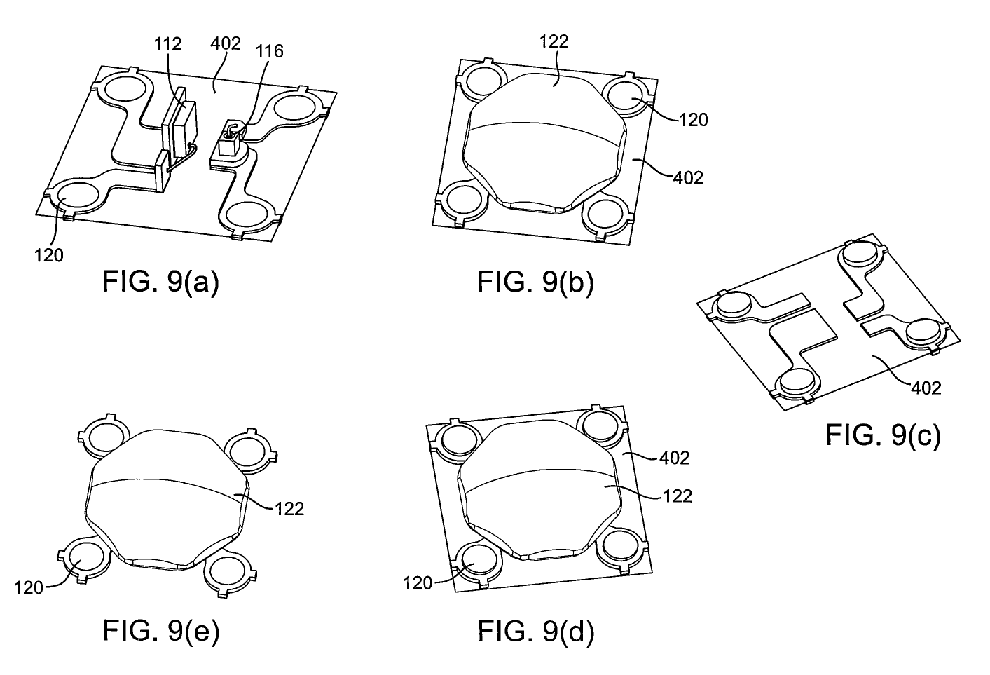

Another method for forming another optocoupler package embodiment can be described with respect to FIGS. 9(a)-9(e).

FIG. 9(a) shows a leadframe structure 120 with an optical receiver device 112 and an optical emitter device 116 mounted on die attach pads, and wirebonding processes are performed, as described above. Then, as shown in FIG. 9(b), an optically transmissive material is deposited on the leadframe structure and the temporary substrate 402 as described above. In this case, the temporary substrate 402 may fill the planar spaces of the leadframe structure 120.

After depositing a light transmissive material 122 on one side of the leadframe structure 204, as shown in FIG. 9(c), the entire precursor is turned over so that the bottom of the leadframe structure 120 can be covered with another light transmissive material 122 or other covering material (e.g., an opaque material). As shown in FIG. 9(d), the light transmissive material 122 is deposited on the temporary substrate 402. After the light transmissive material 122 is deposited on the backside of the leadframe structure 120, the temporary substrate 120 portions that are not covered by the material 122 can be removed as shown in FIG. 9(e).

Then, a molding process and bumping process can be performed (e.g., as described above with respect to FIG. 7(b)) to form the final optocoupler package.

Embodiments of the invention may be used in systems including computers, power supply systems, etc.

While the foregoing is directed to certain preferred embodiments of the present invention, other and further embodiments of the invention may be devised without departing from the basic scope of the invention. Such alternative embodiments are intended to be included within the scope of the present invention. Moreover, the features of one or more embodiments of the invention may be combined with one or more features of other embodiments of the invention without departing from the scope of the invention.

What is claimed is:

1. A package comprising:
a leadframe structure comprising a first die attach pad comprising a first die attach pad surface and a second die attach pad comprising a second die attach pad surface;
a first device on the first die attach pad; and
a second device on second die attach pad, wherein the second device is oriented at an angle with respect to the first device.

2. An optocoupler package comprising:
a leadframe structure comprising a first die attach pad comprising a first die attach pad surface and a second die attach pad comprising a second die attach pad surface;
an optical emitter device on the first die attach pad;
an optical receiver device on second die attach pad, wherein the optical receiver device is oriented at an angle with respect to the optical emitter device; and
an optically transmissive medium disposed between the optical emitter device and the optical receiver device.

3. The optocoupler package of claim 2 wherein the first die attach pad surface is oriented at an angle with respect to the second die attach pad surface.

4. The optocoupler package of claim 3 wherein the angle is about 90 degrees.

5. The optocoupler package of claim 2 further comprising a reflective coating on the optically transmissive medium.

6. The optocoupler package of claim 3 wherein the leadframe structure comprises a first bonding pad and a second bonding pad, and wherein the optocoupler package further comprises a first wire coupling the optical emitter device to the first bonding pad and a second wire coupling the optical receiver device to the second bonding pad.

7. The optocoupler package of claim 2 further comprising a molding material around the optically transmissive medium.

8. The optocoupler package of claim 2 wherein the optically transmissive medium comprises silicone.

9. The optocoupler package of claim 2 wherein the optical receiver device and the optical emitter device are on one side of the leadframe structure and wherein the optocoupler package further comprises a plurality of conductive structures disposed at a second side of the leadframe structure, wherein the first side of the leadframe structure is opposite to the second side of the leadframe structure.

10. The optocoupler package of claim 9 wherein the plurality of conductive structures comprise solder.

11. An optocoupler apparatus comprising:
a) a circuit substrate; and
b) the optocoupler package of claim 10 mounted on the circuit substrate.

12. A method comprising:
obtaining a leadframe structure comprising a first die attach pad comprising a first die attach pad surface and a second die attach pad comprising a second die attach pad surface;
attaching a first device to the first die attach pad; and
attaching a second device to the second die attach pad, wherein the second device is oriented at an angle with respect to the second device.

13. A method comprising:
obtaining a leadframe structure comprising a first die attach pad comprising a first die attach pad surface and a second die attach pad comprising a second die attach pad surface;
attaching an optical emitter device to the first die attach pad;
attaching an optical receiver device to the second die attach pad, wherein the optical receiver device is oriented at an angle with respect to the optical emitter device; and
depositing an optically transmissive medium between the optical emitter device and the optical receiver device.

14. The method of claim 13 wherein the first die attach pad surface is oriented at an angle with respect to the second die attach pad surface.

15. The method of claim 13 wherein the angle is about 90 degrees.

16. The method of claim 13 further comprising depositing a reflective coating on the optically transmissive medium.

17. The method of claim 13 wherein the leadframe structure comprises a first bonding pad and a second bonding pad, and wherein the optocoupler package further comprises a first wire coupling the optical emitter device to the first bonding pad and a second wire coupling the optical receiver device to the second bonding pad.

18. The method of claim 13 further comprising molding a molding material around the optically transmissive medium.

19. The method of claim 13 wherein the optical receiver device and the optical emitter device are on one side of the leadframe structure and wherein the optocoupler package further comprise a plurality of conductive structures disposed at a second side of the leadframe structure, wherein the first side of the leadframe structure is opposite to the second side of the leadframe structure.

20. The method of claim 13 further comprising turning the leadframe structure before depositing.
